(19) United States
(12) Patent Application Publication
(10) Pub. No.: US 2016/0226519 A1
(43) Pub. Date: Aug. 4, 2016

(54) METHOD AND DEVICE FOR COMPRESSING FIRMWARE PROGRAM, METHOD AND DEVICE FOR DECOMPRESSING FIRMWARE PROGRAM

(71) Applicant: Xiaomi Inc., Beijing (CN)

(72) Inventors: Deguo MENG, Beijing (CN); Xin LIU, Beijing (CN); Enxing HOU, Beijing (CN)

(73) Assignee: Xiaomi Inc., Beijing (CN)

(21) Appl. No.: 15/010,448

(22) Filed: Jan. 29, 2016

(30) Foreign Application Priority Data
Jan. 29, 2015 (CN) 201510044885.X

(51) Int. Cl. H03M 7/30; G06F 9/45

(52) U.S. Cl. CPC H03M 7/6058; G06F 8/4434

(57) ABSTRACT

A method and a device are provided for compressing/decompressing a firmware program in the field of computer technology. The method includes: acquiring a code portion and a data portion of the firmware program; compressing the code portion and the data portion separately; and configuring first description data corresponding to the firmware program, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

### CROSS-REFERENCE TO RELATED APPLICATION

The present application is based upon and claims priority to Chinese Patent Application No. 201510044885.X, filed Jan. 29, 2015, the entire contents of which are incorporated herein by reference.

### TECHNICAL FIELD

The present disclosure generally relates to the field of computer technology, and more particularly, to a method and a device for compressing a firmware program, and a method and a device for decompressing a firmware program.

### BACKGROUND

Firmware refers to software working at the bottom layer of an electronic device, to support the normal operation of the electronic device. Generally, the more functions of the electronic device has, the larger the firmware will be, and the larger storage space required to store the firmware program will be.

In order to reduce the storage space occupied by the firmware program in the electronic device, in the related art, the firmware program as a whole will be compressed. Before it runs the firmware program, the electronic device decompresses the compressed firmware program. Then, based on a first decompression address corresponding to a decompressed code portion, the decompressed code portion of the firmware program is copied to the first decompression address; and based on a second decompression address corresponding to a decompressed data portion, the decompressed data portion is copied to the second decompression address.

### SUMMARY

According to a first aspect of embodiments of the present disclosure, there is provided a method for compressing a firmware program. In the method, the server acquires a code portion and a data portion of the firmware program. The server compresses the code portion and the data portion separately. The server configures first description data corresponding to the firmware program. The first description data include first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

According to a second aspect of embodiments of the present disclosure, there is provided a method for decompressing a firmware program. In the method, the device retrieves first description data corresponding to the firmware program, the first description data containing first address data regarding where a compressed code portion of the firmware program is stored in an electronic device, second address data regarding where a compressed data portion of the firmware program is stored in the electronic device, a first decompression address where the compressed code portion is to be decompressed in the electronic device, and a second decompression address where the compressed data portion is to be decompressed in the electronic device. The device acquires the compressed code portion based on the first address data, and acquiring the compressed data portion based on the second address data. The device decompresses the compressed code portion to the first decompression address, and decompressing the compressed data portion to the second decompression address.

According to a third aspect of embodiments of the present disclosure, there is provided a device for compressing a firmware program, including: a processor; and a memory for storing instructions executable by the processor. The processor is configured to perform: acquiring a code portion and a data portion of the firmware program; compressing the code portion and the data portion separately; and configuring first description data corresponding to the firmware program, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

According to a fourth aspect of embodiments of the present disclosure, there is provided a device for compressing a firmware program, including: a processor; and a memory for storing instructions executable by the processor. The processor is configured to perform: retrieving first description data corresponding to the firmware program, the first description data containing first address data regarding where a compressed code portion of the firmware program is stored in an electronic device, second address data regarding where a compressed data portion of the firmware program is stored in the electronic device, a first decompression address where the compressed code portion is to be decompressed in the electronic device, and a second decompression address where the compressed data portion is to be decompressed in the electronic device; acquiring the compressed code portion based on the first address data, and acquiring the compressed data portion based on the second address data; and decompressing the compressed code portion to the first decompression address, and decompressing the compressed data portion to the second decompression address.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments consistent with the invention and, together with the description, serve to explain the principles of the invention.

FIG. 1 is a flow chart showing a method for compressing a firmware program according to an exemplary embodiment.

FIG. 2A is a flow chart showing a method for compressing a firmware program according to another exemplary embodiment.

FIG. 2B is a flow chart showing a process for determining a third storage address and a fourth storage address according to another exemplary embodiment.

FIG. 2C is a flow chart showing a process for configuring first description data according to another exemplary embodiment.

FIG. 2D is a flow chart showing another process for configuring first description data according to another exemplary embodiment.

FIG. 2E is a flow chart showing a possible process for compressing a code portion and a data portion according to another exemplary embodiment.

FIG. 3 is a flow chart showing a method for decompressing a firmware program according to an exemplary embodiment.

FIG. 4A is a flow chart showing a method for decompressing a firmware program according to another exemplary embodiment.

FIG. 4B is a flow chart showing a process for determining a first storage address and a second storage address according to another exemplary embodiment.

FIG. 4C is a flow chart showing a process for examining an error of the firmware program according to another exemplary embodiment.

FIG. 5 is a block diagram of a device for compressing a firmware program according to an exemplary embodiment.

FIG. 6A is a block diagram of a device for compressing a firmware program according to another exemplary embodiment.

FIG. 6B is a block diagram of an address determining sub-module according to another exemplary embodiment.

FIG. 6C is a block diagram of a compressing module according to another exemplary embodiment.

FIG. 7 is a block diagram of a device for decompressing a firmware program according to an exemplary embodiment.

FIG. 8A is a block diagram of a device for decompressing a firmware program according to another exemplary embodiment.

FIG. 8B is a block diagram of an address determining sub-module according to another exemplary embodiment.

FIG. 9 is a block diagram of a device for compressing a firmware program according to an exemplary embodiment.

FIG. 10 is a block diagram of a device for decompressing a firmware program according to an exemplary embodiment.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

Reference throughout this specification to “one embodiment,” “an embodiment,” “exemplary embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may be combined in any suitable manner.

The terminology used in the description of the disclosure herein is for the purpose of describing particular examples only and is not intended to be limiting of the disclosure. As used in the description of the disclosure and the appended claims, the singular forms “a,” “an,” and “the” are intended to include the plural forms as well, unless the context clearly indicates otherwise. Also, as used in the description herein and throughout the claims that follow, the meaning of “in” includes “in” and “on” unless the context clearly dictates otherwise. It will also be understood that the term “and/or” as used herein refers to and encompasses any and all possible combinations of one or more of the associated listed items. It will be further understood that the terms “may include,” “including,” “comprises,” and/or “comprising,” when used in this specification, specify the presence of stated features, operations, elements, and/or components, but do not preclude the presence or addition of one or more other features, operations, elements, components, and/or groups thereof.

Firstly, for easy understanding, the terms used in the embodiments are briefly explained.

A code portion, also referred to as txt segment, contains therein executable codes of a firmware program.

A data portion, also referred to as data portion, contains therein global static data required in running of codes of a firmware program.

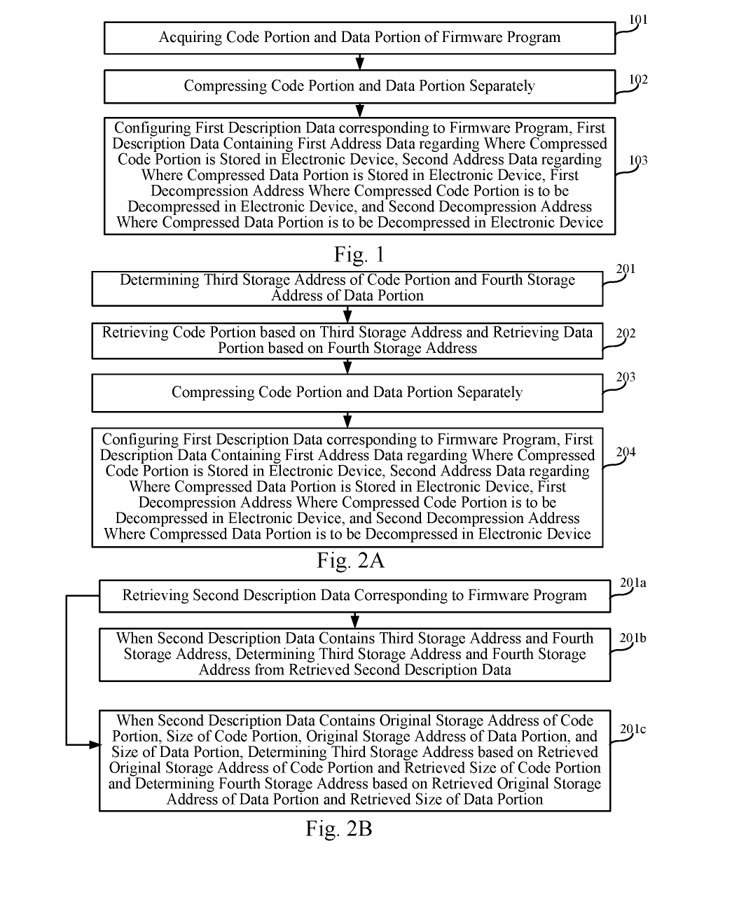

FIG. 1 is a flow chart showing a method for compressing a firmware program according to an exemplary embodiment. As shown in FIG. 1, the method for compressing a firmware program may include the following steps. The method may be implemented by a server.

In step 101, the server acquires a code portion and a data portion of the firmware program. The server may acquire the code portion when the code portion is updated while the data portion is kept the same. Alternatively, the server may acquire the data portion when the data portion is updated.

In step 102, the server compresses the code portion and the data portion separately. The server may use different algorithms to compress the code portion and the data portion when needed.

In step 103, first description data corresponding to the firmware program is configured, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

Accordingly, in the method for compressing a firmware program provided in the embodiment of the present disclosure, the code portion and the data portion of the firmware program are compressed separately; first description data corresponding to the firmware program is configured, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device. Thereby, when it needs to run the firmware program, the electronic device may directly acquire the compressed code portion and the compressed data portion based on the first description data, and respectively decompress the compressed code portion and the compressed data portion to the first decompression address and the second first decompression address. Thus, the disclosure solves the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

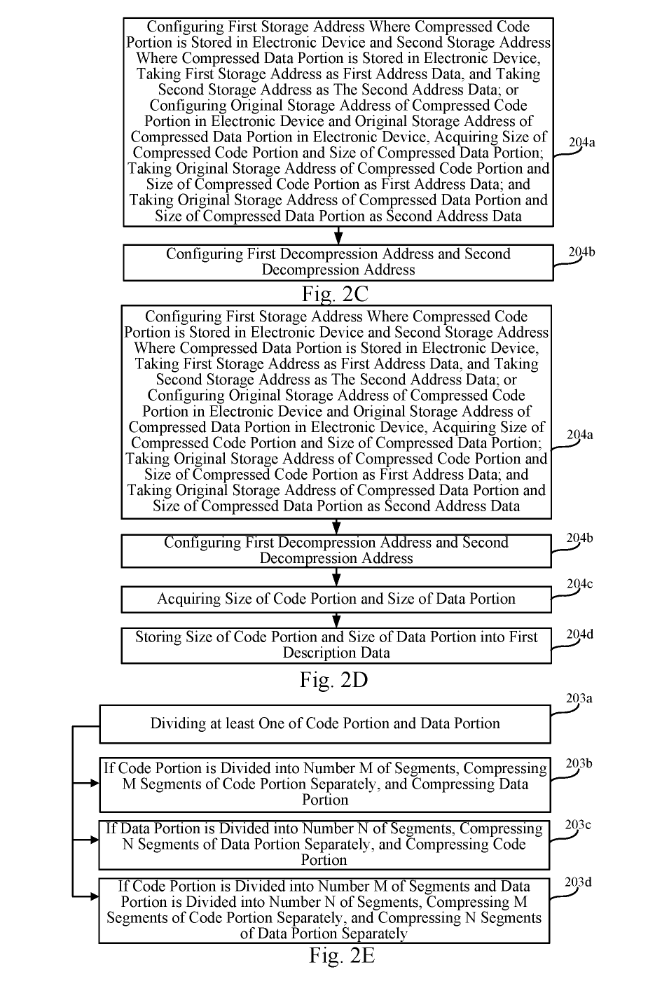

FIG. 2A is a flow chart showing a method for compressing a firmware program according to an exemplary embodiment. As shown in FIG. 2A, the method for compressing a firmware program may include the following steps.

In step 201, the server determines a third storage address of the code portion and a fourth storage address of the data portion.

For example, when the firmware program is stored in a server, and includes a code portion and a data portion. When the server needs to compress the firmware program, the server may determine a third storage address of the code portion in the server and a fourth storage address of the data portion in the server. The third storage address of the code portion indicates the starting address of the code portion in the server. The fourth storage address of the data portion indicates the starting address of the data portion in the server.

Referring to FIG. 2B, the present step may include the following steps.

In step 201a, the server retrieves the second description data corresponding to the firmware program.

The server may store a store second description data corresponding to a firmware program together with the stored firmware program. The second description data may contain the third storage address and the fourth storage address, or it may contain an original storage address of the code portion, a size of the code portion, an original storage address of the data portion, and a size of the data portion. Thus, the server may determine the third storage address and the fourth storage address by retrieving the second description data.

In step 201b, when the second description data contains the third storage address and the fourth storage address, the third storage address and the fourth storage address are determined from the retrieved second description data.

In step 201c, when the second description data contains an original storage address of the code portion, a size of the code portion, an original storage address of the data portion, and a size of the data portion, the third storage address is determined based on the retrieved original storage address of the code portion and the retrieved size of the code portion and the fourth storage address is determined based on the retrieved original storage address of the data portion and the retrieved size of the data portion.

For example, if the second description data contains an original storage address D1 of the code portion, a size S1 of the code portion, a storage space required to store the code portion having the size S1 will be d1, and the third storage address may be determined as D1˜D1+d1.

In step 202, the server retrieves the code portion based on the third storage address and the data portion is retrieved based on the fourth storage address.

After it determines the third storage address and the fourth storage address, the server may retrieve the code portion from the third storage address and retrieve the data portion from the fourth storage address.

For example, the server may retrieve the code portion from the address D1˜D1+d1.

In step 203, the server compresses the code portion and the data portion separately.

The server compresses the retrieved code portion and compresses the retrieved data portion.

In step 204, first description data corresponding to the firmware program is configured, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

After it compresses the code portion and the data portion separately, the server may configure a corresponding first description data.

Referring to FIG. 2C, the present step may include the following steps.

In step 204a, a first storage address where the compressed code portion is stored in the electronic device and a second storage address where the compressed data portion is stored in the electronic device are configured, the first storage address is taken as the first address data, and the second storage address is taken as the second address data; or, an original storage address of the compressed code portion in the electronic device and an original storage address of the compressed data portion in the electronic device are configured, a size of the compressed code portion and a size of the compressed data portion are acquired; the original storage address of the compressed code portion and the size of the compressed code portion are taken as the first address data; and the original storage address of the compressed data portion and the size of the compressed data portion are taken as the second address data.

Since a firmware program is typically adapted to an electronic device of a designated type and the electronic device typically has a certain storage space, the server may configure a first storage address where the compressed code portion is stored in the electronic device and a second storage address where the compressed data portion is stored in the electronic device, take the first storage address as the first address data, and take the second storage address as the second address data. Here, the server may configure a first storage address where the compressed code portion is stored in a Flash of the electronic device and a second storage address where the compressed data portion is stored in the Flash of the electronic device

Alternatively, the server may only configure an original storage address of the compressed code portion in the electronic device and an original storage address of the compressed data portion in the electronic device; then acquire respectively a size of the compressed code portion and a size of the compressed data portion; and finally, take the original storage address of the compressed code portion in the electronic device and the size of the compressed code portion as the first address data; and take the original storage address of the compressed data portion in the electronic device and the size of the compressed data portion as the second address data.

In step 204b, the first decompression address and the second decompression address are configured.

Since a firmware program is typically adapted to an electronic device of a designated type and the electronic device typically has a certain storage space, the server may configure in advance a first decompression address in the electronic device which corresponds to the compressed code portion and a second decompression address in the electronic device which corresponds to the compressed data portion.

It should be noted that, in the disclosure, as an example, the step 204a is performed before the step 204b. Alternatively or additionally, the server may perform the step 204a and the step 204b simultaneously, or perform the step 204b before the step 204a, which is not limited in the disclosure.

It should be further noted that, in the disclosure, as an example, the first description data is configured separately. Alternatively or additionally, the server may also configure the contents of the first description data in the second description data. This is not limited in the present disclosure.

Accordingly, in the method for compressing a firmware program provided in the embodiment of the present disclosure, the code portion and the data portion of the firmware program are compressed separately; first description data corresponding to the firmware program is configured, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device. Thereby, when it needs to run the firmware program, the electronic device may directly acquire the compressed code portion and the compressed data portion based on the first description data, and respectively decompress the compressed code portion and the compressed data portion to the first decompression address and the second first decompression address. Thus, it may solve the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

In the disclosure, the code portion and the data portion of the firmware program are compressed separately, thereby, the electronic device may directly decompress the compressed code portion to the first decompression address, and directly decompress the compressed data portion to the second decompression address, rather than decompressing the firmware program as a whole and then copying it to a corresponding decompression address. Thus, it may eliminate the need to reserve a space in the memory of the electronic device to store the decompressed firmware program and may improve the utilization of the space of the memory of the electronic device.

It should be noted that, as shown in FIG. 2D, in the above embodiments, the step of the server configuring the first description data corresponding to the firmware program further includes the following steps.

In step 204c, a size of the code portion and a size of the data portion are acquired.

The server may also acquire a size of the uncompressed code portion and a size of the uncompressed data portion.

Alternatively or additionally, when both of the sizes are contained in the second description data, the server may retrieve the above contents from the second description data.

When the second description data contains the third storage address of the code portion and the fourth storage address of the data portion, the server may determine the size of the code portion from the range of the third storage address, and determine the size of the data portion from the range of the fourth storage address. This is not limited in the disclosure.

In step 204d, the size of the code portion and the size of the data portion are stored into the first description data.

The server may store into the first description data the size of the code portion and the size of the data portion as acquired.

However, if the contents of the first description data are directly configured in the second description data, the server may store into the second description data the size of the code portion and the size of the data portion as acquired. This is not limited in the disclosure. In addition, if the second description data has already contained both the above sizes, the server may skip the step 204c and the step 204d. This is not either limited in the disclosure.

Further, in the disclosure, the performing sequence of the step 204a, the step 204b and the step 204c is not limited, and the server may perform according to other sequences depending on a practical application.

It should be further noted that, in the above embodiment, as shown in FIG. 2E, the step 203 may include the following steps.

In step 203a, at least one of the code portion and the data portion is divided.

After it acquires the code portion and the data portion of the firmware program, the server may divide the code portion or the data portion, or may divide both of them.

For example, the server divides the code portion and it may divide the code portion into a number m of segments.

Alternatively or additionally, after the dividing, each segment of the code portion may have the same length or different lengths. Similarly, after the dividing, each segment of the data portion may have the same length or different lengths.

In step 203b, if the code portion is divided into a number m of segments, the m segments of the code portion are compressed separately, and the data portion is compressed.

If the server divides the code portion into a number m of segments, the server may compress the m segments of the code portion separately, and further compress the data portion.

Correspondingly, the first address data configured by the server may include address data of each of the m compressed segments in the electronic device, and the first decompressed address configured by the server includes a decompression address corresponding to each of the m compressed segments in the electronic device.

In step 203c, if the data portion is divided into a number n of segments, the n segments of the data portion are compressed separately, and the code portion is compressed.

If the server divides the data portion into a number n of segments, the server may compress the n segments of the data portion separately, and compress the code portion.

Correspondingly, the second address data configured by the server may include address data of each of the n compressed segments in the electronic device, and the second decompressed address configured by the server includes a decompression address corresponding to each of the n compressed segments in the electronic device.

In step 203d, if the code portion is divided into a number m of segments and the data portion is divided into a number n of segments, the m segments of the code portion are compressed separately, and the n segments of the data portion are compressed separately.

Similarly, if it divides the code portion into a number m of segments and divides the data portion into a number n of segments, the server may compress the m segments of the divided code portion separately and compress the n segments of the divided data portion separately.

Correspondingly, in this case, the first address data configured by the server may include address data of each of the m compressed segments in the electronic device; the first decompressed address configured by the server includes a decompression address corresponding to each of the m compressed segments in the electronic device; the second address data configured by the server may include address data of each of the n compressed segments in the electronic device; and the second decompressed address configured by the server includes a decompression address corresponding to each of the n compressed segments in the electronic device.

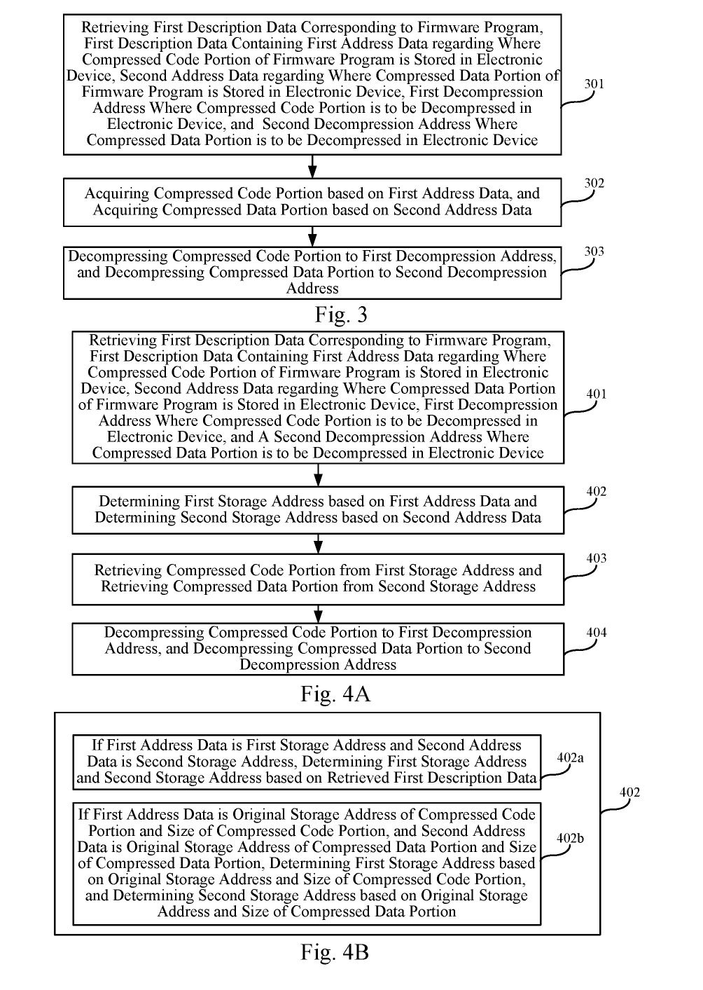

FIG. 3 is a flow chart showing a method for decompressing a firmware program according to an exemplary embodiment. As shown in FIG. 3, the method for decompressing a firmware program may include the following steps.

In step 301, first description data corresponding to the firmware program is retrieved, the first description data containing first address data regarding where a compressed code portion of the firmware program is stored in an electronic device, second address data regarding where a compressed data portion of the firmware program is stored in the electronic device, a first decompression address where the compressed code portion is to be decompressed in the electronic device, and a second decompression address where the compressed data portion is to be decompressed in the electronic device.

In step 302, the compressed code portion is acquired based on the first address data, and the compressed data portion is acquired based on the second address data.

In step 303, the compressed code portion is decompressed to the first decompression address, and the compressed data portion is decompressed to the second decompression address.

Accordingly, in the method for decompressing a firmware program provided in the embodiment of the present disclosure, first description data is retrieved, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device; the compressed code portion is acquired based on the retrieved first address data, and the compressed data portion is acquired based on the retrieved second address data; the compressed code portion is decompressed to the first decompression address, and the compressed data portion is decompressed to the second decompression address. Thereby, it may solve the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

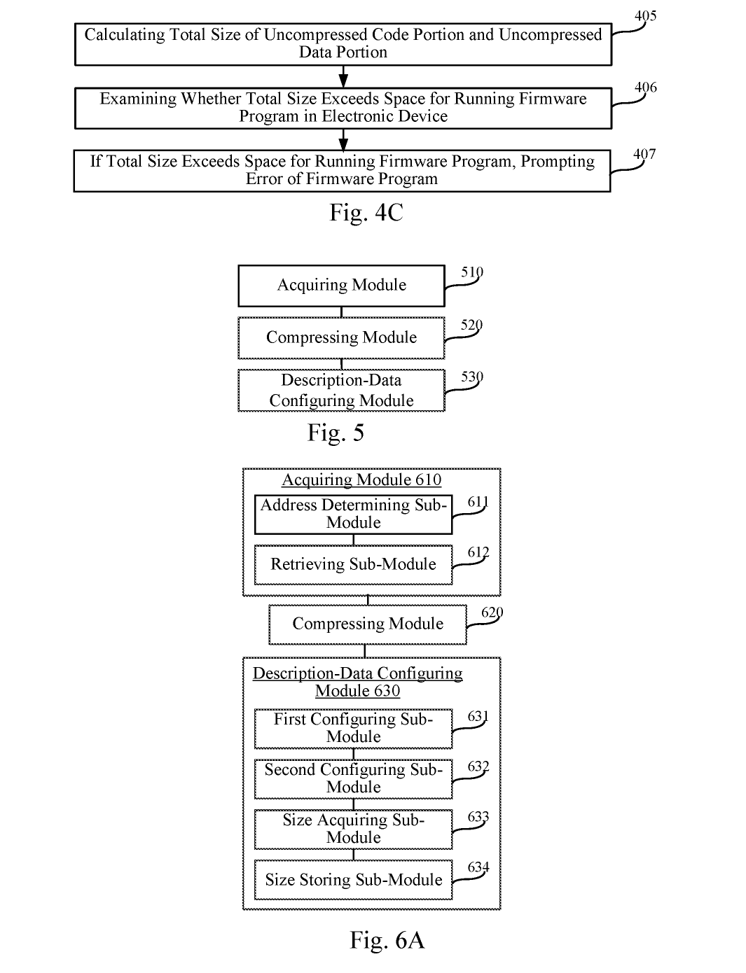

FIG. 4A is a flow chart showing a method for decompressing a firmware program according to an exemplary embodiment. As shown in FIG. 4A, the method for decompressing a firmware program may include the following steps.

In step 401, first description data corresponding to the firmware program is retrieved, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

The electronic device may acquire the firmware program from the server over a network, or, the electronic device may acquire the firmware program from a recovery device or a mobile storage device. The firmware program is typically a compressed firmware, and typically includes a compressed code portion, a compressed data portion and first description data. Wherein, the first description data contains first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device. In addition, the firmware program in the recovery device or the mobile storage device may be firmware program acquired in advance from a server. This is not limited in the disclosure.

When it needs to run the firmware program, the electronic device may retrieve the first description data.

In step 402, a first storage address is determined based on the first address data and a second storage address is determined based on the second address data.

After the first address data and the second address data are retrieved from the first description data, the electronic device may determine a first storage address based on the first address data and determine a second storage address based on the second address data.

Referring to FIG. 4B, the present step may include:

In step 402a, if the first address data is the first storage address and the second address data is the second storage address, the first storage address and the second storage address are determined based on the retrieved first description data.

In step 402b, if the first address data is an original storage address of the compressed code portion and a size of the compressed code portion, and the second address data is an original storage address of the compressed data portion and a size of the compressed data portion, the first storage address is determined based on the original storage address and the size of the compressed code portion, and the second storage address is determined based on the original storage address and the size of the compressed data portion.

The present step is similar to the step 201c in the above embodiment, which will not be repeated in the disclosure.

In step 403, the compressed code portion is retrieved from the first storage address and the compressed data portion is retrieved from the second storage address.

In step 404, the compressed code portion is decompressed to the first decompression address, and the compressed data portion is decompressed to the second decompression address.

After it retrieves the compressed code portion and the compressed data portion, the electronic device may decompress the compressed code portion to the first decompression address, and decompress the compressed data portion to the second decompression address.

After it decompresses the compressed code portion and the compressed data portion, the electronic device may turn to the beginning of the code portion to run the code portion.

Accordingly, in the method for decompressing a firmware program provided in the embodiment of the present disclosure, first description data is retrieved, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device; the compressed code portion is acquired based on the retrieved first address data, and the compressed data portion is acquired based on the retrieved second address data; the compressed code portion is decompressed to the first decompression address, and the compressed data portion is decompressed to the second decompression address. Thereby, it may solve the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

In the disclosure, the code portion and the data portion of the firmware program are compressed separately, thereby, the electronic device may directly decompress the compressed code portion to the first decompression address, and directly decompress the compressed data portion to the second decompression address, rather than decompressing the firmware program as a whole and then copying it to a corresponding decompression address. Thus, it may eliminate the need to reserve a space in the memory of the electronic device to store the decompressed firmware program and may improve the utilization of the space of the memory of the electronic device.

It should be noted that, as shown in FIG. 4C, in the above embodiment, the first description data may also contain a size of an uncompressed code portion and a size of an uncompressed data portion, and the method further includes the following steps.

In step 405, a total size of the uncompressed code portion and the uncompressed data portion is calculated.

When the first description data also contains a size of the uncompressed code portion and a size of the uncompressed data portion, after it retrieves the first description data, the electronic device may calculate a sum of the size of the uncompressed code portion and the size of the uncompressed data portion, to obtain a total size of the uncompressed code portion and the uncompressed data portion.

In step 406, it is examined whether the total size exceeds a space for running the firmware program in the electronic device.

It is examined whether the calculated total size exceeds a preserved space for running the firmware program in the electronic device. The space for running the firmware program refers to a memory space preserved by the electronic device for running the firmware program.

In step 407, if the total size exceeds a space for running the firmware program, an error of the firmware program is prompted.

If the electronic device examines that the total size exceeds the space for running the firmware program, it means that the firmware program is not adapted for the electronic device of such type, and then, the electronic device may prompt an error of the firmware program.

It should be noted that, the above steps are generally performed before the step 404. If it is examined that the total size exceeds the space for running the firmware program, the electronic device will not perform the step 404, and only when it is examined that the total size does not exceed the space for running the firmware program, the electronic device will perform the step 404. This is not limited in the disclosure.

In the disclosure, the total size of the code portion and the data portion are calculated, thereby, it may prompt the user if the firmware program has an error.

It should be further noted that, the step 402 may include the following steps.

If the first address data contains address data of each of the m compressed segments, the electronic device may determine a storage address of each segment based on the address data of the segment. That is to say, the first storage address contains the storage data of each of the m compressed segments in the electronic device.

Subsequently, the electronic device may retrieve a code segment stored at each storage address, and decompress the retrieved code segment to a decompression address in the first decompression address which corresponds to this code segment. For example, for an i-th code segment of the m segments, based on address data of the i-th code segment in the first address data, the electronic device may determine the storage address of the i-th code segment, then retrieve the i-th code segment from the storage address of the i-th code segment, and decompress the retrieved i-th code segment to a decompression address in the first decompression address which corresponds to the i-th code segment.

Similarly, if the second address data contains address data of each of the n segments of the compressed data portion, the electronic device may determine a storage address of each segment based on the address data of the segment. That is to say, the second storage address contains the storage data of each of the n compressed segments in the electronic device.

Subsequently, the electronic device may retrieve a data segment stored at each storage address, and decompress the retrieved data segment to a decompression address in the second decompression address which corresponds to this data segment. This is similar to the process of the m segments of the compressed code portion, which will not be repeated in the disclosure.

It should be further noted that, in the above embodiments, the compressed firmware program as stored includes a code portion, a data portion and description data. Wherein, the description data contains first address data for the compressed code portion of the firmware program, second address data for the compressed data portion of the firmware program, a first decompression address corresponding to the compressed code portion, and a second decompression address corresponding to the compressed data portion. Alternatively or additionally, the description data may also contain a size of the uncompressed code portion and a size of the uncompressed data portion. However, the description data may also contain other information, which is not limited in the disclosure.

In the following embodiments of devices according to the present disclosure, the devices may be configured to perform the method in the above embodiments of the present disclosure. Details are not disclosed in the embodiments of devices may be referred to the embodiments of methods.

FIG. 5 is a block diagram of a device for compressing a firmware program according to an exemplary embodiment. As shown in FIG. 5, the device for compressing a firmware program may include but not limited to: an acquiring module 510, a compressing module 520 and a description-data configuring module 530.

The acquiring module 510 is configured to acquire a code portion and a data portion of the firmware program;

the compressing module 520 is configured to compress the code portion and the data portion separately; and

the description-data configuring module 530 is configured to configure first description data corresponding to the firmware program, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

Accordingly, in the device for compressing a firmware program provided in the embodiment of the present disclosure, the code portion and the data portion of the firmware program are compressed separately; first description data corresponding to the firmware program is configured, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device. Thereby, when it needs to run the firmware program, the electronic device may directly acquire the compressed code portion and the compressed data portion based on the first description data, and respectively decompress the compressed code portion and the compressed data portion to the first decompression address and the second first decompression address. Thus, it may solve the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

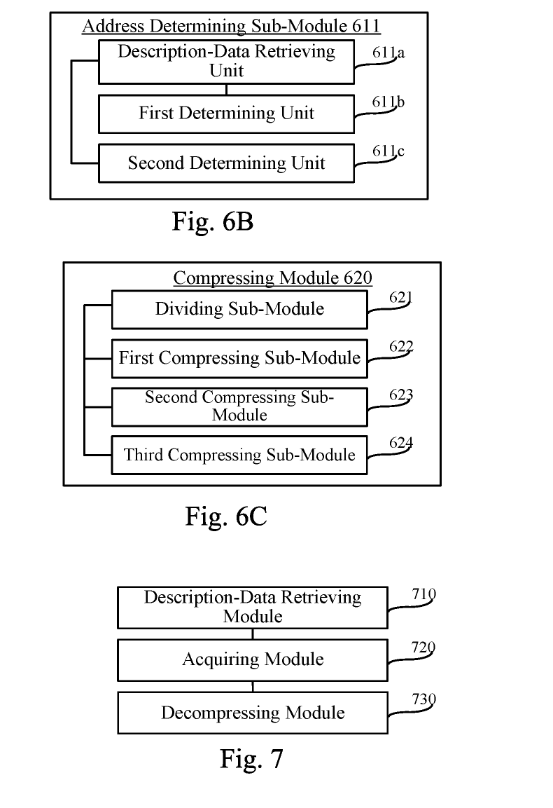

FIG. 6A is a block diagram of a device for compressing a firmware program according to an exemplary embodiment. As shown in FIG. 6A, the device for compressing a firmware program may include but not limited to: an acquiring module 610, a compressing module 620 and a description-data configuring module 630.

The acquiring module 610 is configured to acquire a code portion and a data portion of the firmware program;

the compressing module 620 is configured to compress the code portion and the data portion separately; and

the description-data configuring module 630 is configured to configure first description data corresponding to the firmware program, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

Alternatively or additionally, the acquiring module 610 includes: an address determining sub-module 611 and a retrieving sub-module 612. The address determining sub-module 611 is configured to determine a third storage address of the code portion and a fourth storage address of the data portion. The retrieving sub-module 612 is configured to retrieve the code portion based on the third storage address and retrieve the data portion based on the fourth storage address.

Alternatively or additionally, as shown in FIG. 6B, the address determining sub-module 611 includes: a description-data retrieving unit 611a, a first determining unit 611b, and a second determining unit 611c.

The description-data retrieving unit 611a is configured to retrieve second description data corresponding to the firmware program. The first determining unit 611b is configured to determine the third storage address and the fourth storage address from the retrieved second description data when the second description data contains the third storage address and the fourth storage address. The second determining unit 611c is configured to, when the second description data contains an original storage address of the code portion, a size of the code portion, an original storage address of the data portion, and a size of the data portion, determine the third storage address based on the retrieved original storage address of the code portion and the retrieved size of the code portion and determining the fourth storage address based on the retrieved original storage address of the data portion and the retrieved size of the data portion.

Alternatively or additionally, the description-data configuring module 630 includes: a first configuring sub-module 631 and a second configuring sub-module 632.

The first configuring sub-module 631 is configured to configure a first storage address where the compressed code portion is stored in the electronic device and a second storage address where the compressed data portion is stored in the electronic device, take the first storage address as the first address data, and take the second storage address as the second address data. Alternatively or additionally, the first configuring sub-module 631 configures an original storage address of the compressed code portion in the electronic device and an original storage address of the compressed data portion in the electronic device, acquiring a size of the compressed code portion and a size of the compressed data portion; taking the original storage address of the compressed code portion and the size of the compressed code portion as the first address data; and taking the original storage address of the compressed data portion and the size of the compressed data portion as the second address data.

The second configuring sub-module 632 is configured to configure the first decompression address and the second decompression address.

Alternatively or additionally, the description-data configuring module 630 also includes: a size acquiring sub-module 633 configured to acquire a size of the code portion and a size of the data portion; and a size storing sub-module 634 configured to store the size of the code portion and the size of the data portion into the first description data.

Alternatively or additionally, as shown in FIG. 6C, the compressing module 620 includes: a dividing sub-module 621 configured to divide at least one of the code portion and the data portion; a first compressing sub-module 622 configured to, if the code portion is divided into a number m of segments, compress the m segments of the code portion separately, and compress the data portion; a second compressing sub-module 623 configured to, if the data portion is divided into a number n of segments, compress the n segments of the data portion separately, and compress the code portion; and a third compressing sub-module configured 624 to, if the code portion is divided into a number m of segments and the data portion is divided into a number n of segments, compressing the m segments of the code portion separately, and compressing the n segments of the data portion separately.

Accordingly, in the device for compressing a firmware program provided in the embodiment of the present disclosure, the code portion and the data portion of the firmware program are compressed separately; first description data corresponding to the firmware program is configured, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device. Thereby, when it needs to run the firmware program, the electronic device may directly acquire the compressed code portion and the compressed data portion based on the first description data, and respectively decompress the compressed code portion and the compressed data portion to the first decompression address and the second first decompression address. Thus, it may solve the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

In the disclosure, the code portion and the data portion of the firmware program are compressed separately, thereby, the electronic device may directly decompress the compressed code portion to the first decompression address, and directly decompress the compressed data portion to the second decompression address, rather than decompressing the firmware program as a whole and then copying it to a corresponding decompression address. Thus, it may eliminate the need to reserve a space in the memory of the electronic device to store the decompressed firmware program and may improve the utilization of the space of the memory of the electronic device.

FIG. 7 is a block diagram of a device for decompressing a firmware program according to an exemplary embodiment. As shown in FIG. 7, the device for decompressing a firmware program may include but not limited to: a description-data retrieving module 710, an acquiring module 720 and a decompressing module 730.

The description-data retrieving module 710 is configured to retrieve first description data corresponding to the firmware program, the first description data containing first address data regarding where a compressed code portion of the firmware program is stored in an electronic device, second address data regarding where a compressed data portion of the firmware program is stored in the electronic device, a first decompression address where the compressed code portion is to be decompressed in the electronic device, and a second decompression address where the compressed data portion is to be decompressed in the electronic device. The acquiring module 720 is configured to acquire the compressed code portion based on the first address data, and acquire the compressed data portion based on the second address data. The decompressing module 730 is configured to decompress the compressed code portion to the first decompression address, and decompress the compressed data portion to the second decompression address.

Accordingly, in the method for decompressing a firmware program provided in the embodiment of the present disclosure, first description data corresponding to the firmware program is retrieved, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device; the compressed code portion is acquired based on the retrieved first address data, and the compressed data portion is acquired based on the retrieved second address data; the compressed code portion is decompressed to the first decompression address, and the compressed data portion is decompressed to the second decompression address. Thereby, it may solve the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

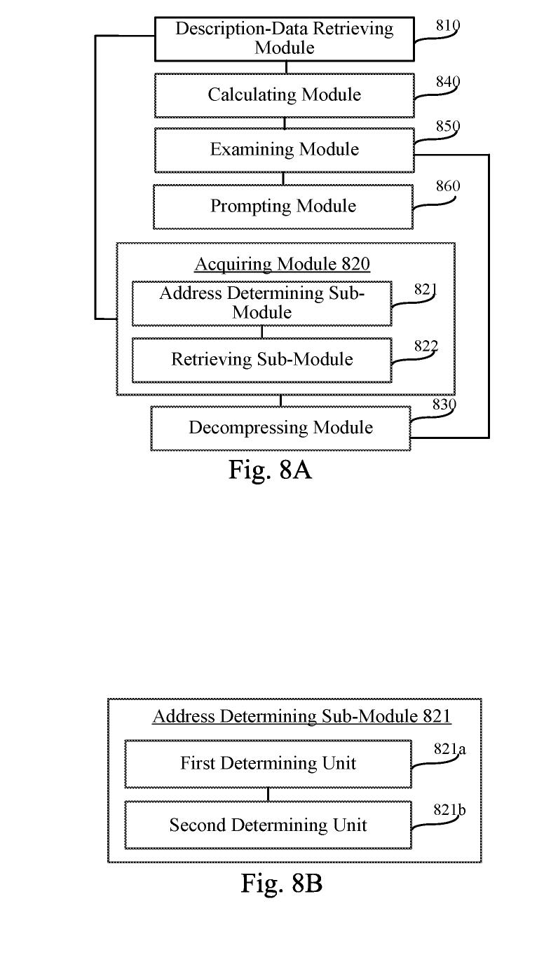

FIG. 8A is a block diagram of a device for decompressing a firmware program according to an exemplary embodiment. As shown in FIG. 8A, the device for decompressing a firmware program may include but not limited to: a description-data retrieving module 810, an acquiring module 820 and a decompressing module 830.

The description-data retrieving module 810 is configured to retrieve first description data corresponding to the firmware program, the first description data containing first address data regarding where a compressed code portion of the firmware program is stored in an electronic device, second address data regarding where a compressed data portion of the firmware program is stored in the electronic device, a first decompression address where the compressed code portion is to be decompressed in the electronic device, and a second decompression address where the compressed data portion is to be decompressed in the electronic device;

the acquiring module 7820 is configured to acquire the compressed code portion based on the first address data, and acquire the compressed data portion based on the second address data; and

the decompressing module 830 is configured to decompress the compressed code portion to the first decompression address, and decompress the compressed data portion to the second decompression address.

Alternatively or additionally, the acquiring module 820 includes: an address determining sub-module 821 configured to determine a first storage address based on the first address data and determine a second storage address based on the second address data; and a retrieving sub-module 822 configured to retrieve the compressed code portion from the first storage address and retrieve the compressed data portion from the second storage address.

Alternatively or additionally, as shown in FIG. 8B, the address determining sub-module 821 includes: a first determining unit 821a configured to, if the first address data is the first storage address and the second address data is the second storage address, determine the first storage address and the second storage address based on the retrieved first description data; and a second determining unit 821b configured to, if the first address data is an original storage address of the compressed code portion and a size of the compressed code portion, and the second address data is an original storage address of the compressed data portion and a size of the compressed data portion, determine the first storage address based on the original storage address and the size of the compressed code portion, and determine the second storage address based on the original storage address and the size of the compressed data portion.

Alternatively or additionally, the first description data further contains a size of an uncompressed code portion of the firmware program and a size of an uncompressed data portion of the firmware program, and the device further includes: a calculating module 840 configured to calculate a total size of the uncompressed code portion and the uncompressed data portion; an examining module 850 configured to examine whether the total size exceeds a space for running the firmware program in the electronic device; and a prompting module 860 configured to, if the total size exceeds a space for running the firmware program, prompt an error of the firmware program.

Accordingly, in the device for decompressing a firmware program provided in the embodiment of the present disclosure, first description data corresponding to the firmware program is retrieved, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device; the compressed code portion is acquired based on the retrieved first address data, and the compressed data portion is acquired based on the retrieved second address data; the compressed code portion is decompressed to the first decompression address, and the compressed data portion is decompressed to the second decompression address. Thereby, it may solve the problem in the related art that after the firmware program is decompressed, the electronic device is required to copy the decompressed code portion and data portion, resulting a complex process. Moreover, it may solve the problem that it is complicated to copy codes and the copy method has poor universality. Therefore, it may achieve an effect of reducing complexity of the process of the electronic device by eliminating the need to copy codes.

In the disclosure, the code portion and the data portion of the firmware program are compressed separately, thereby, the electronic device may directly decompress the compressed code portion to the first decompression address, and directly decompress the compressed data portion to the second decompression address, rather than decompressing the firmware program as a whole and then copying it to a corresponding decompression address. Thus, it may eliminate the need to reserve a space in the memory of the electronic device to store the decompressed firmware program and may improve the utilization of the space of the memory of the electronic device.

With respect to the devices in the above embodiments, the specific manners for performing operations for individual modules therein have been described in detail in the embodiments regarding the relevant methods, which will not be elaborated herein.

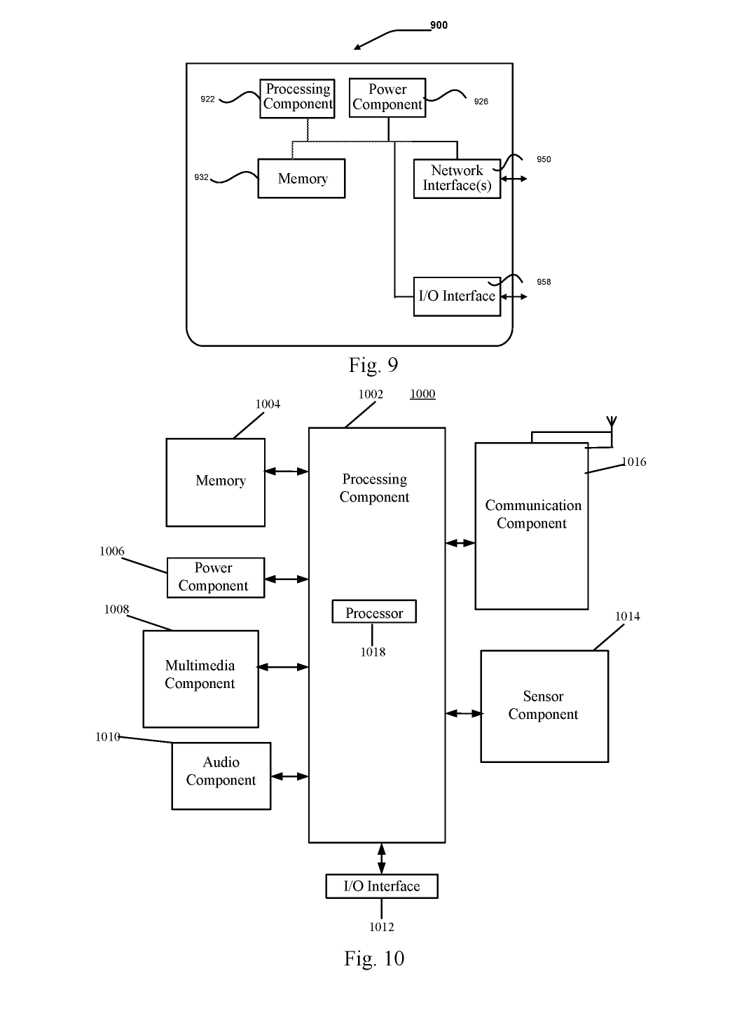

FIG. 9 is a block diagram of a device 900 for compressing a firmware program, according to an exemplary embodiment. For example, the device 900 may be provided as a server. Referring to FIG. 9, the device 900 includes a processing component 922 that further includes one or more processors, and memory resources represented by a memory 932 for storing instructions executable by the processing component 922, such as application programs. The application programs stored in the memory 932 may include one or more modules each corresponding to a set of instructions. Further, the processing component 922 is configured to execute the instructions to perform the above described method for compressing a firmware program.

The device 900 may also include a power component 926 configured to perform power management of the device 900, wired or wireless network interface(s) 950 configured to connect the device 900 to a network, and an input/output (I/O) interface 958. The device 900 may operate based on an operating system stored in the memory 932, such as Windows Server™, Mac OS X™, Unix™, Linux™, FreeBSD™, or the like.

FIG. 10 is a block diagram of a device 1000 for decompressing a firmware program, according to an exemplary embodiment. For example, the device 1000 may be a mobile phone, a computer, a digital broadcast terminal, a messaging device, a gaming console, a tablet, a medical device, exercise equipment, a personal digital assistant, and the like.

Referring to FIG. 10, the device 1000 may include one or more of the following components: a processing component 1002, a memory 1004, a power component 1006, a multimedia component 1008, an audio component 1010, an input/output (I/O) interface 1012, a sensor component 1014, and a communication component 1016.

The processing component 1002 typically controls overall operations of the device 1000, such as the operations associated with display, telephone calls, data communications, camera operations, and recording operations. The processing component 1002 may include one or more processors 1018 to execute instructions to perform all or part of the steps in the above described methods. Moreover, the processing component 1002 may include one or more modules which facilitate the interaction between the processing component 1002 and other components. For instance, the processing component 1002 may include a multimedia module to facilitate the interaction between the multimedia component 1008 and the processing component 1002.

The memory 1004 is configured to store various types of data to support the operation of the device 1000. Examples of such data include instructions for any applications or methods operated on the device 1000, contact data, phonebook data, messages, pictures, video, etc. The memory 1004 may be implemented using any type of volatile or non-volatile memory devices, or a combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic or optical disk.

The power component 1006 provides power to various components of the device 1000. The power component 1006 may include a power management system, one or more power sources, and any other components associated with the generation, management, and distribution of power in the device 1000.

The multimedia component 1008 includes a screen providing an output interface between the device 1000 and the user. In some embodiments, the screen may include a liquid crystal display (LCD) and a touch panel (TP). If the screen includes the touch panel, the screen may be implemented as a touch screen to receive input signals from the user. The touch panel includes one or more touch sensors to sense touches, swipes, and gestures on the touch panel. The touch sensors may not only sense a boundary of a touch or swipe action, but also sense a period of time and a pressure associated with the touch or swipe action. In some embodiments, the multimedia component 1008 includes a front camera and/or a rear camera. The front camera and the rear camera may receive an external multimedia datum while the device 1000 is in an operation mode, such as a photographing mode or a video mode. Each of the front camera and the rear camera may be a fixed optical lens system or have focus and optical zoom capability.

The audio component 1010 is configured to output and/or input audio signals. For example, the audio component 1010 includes a microphone (“MIC”) configured to receive an external audio signal when the device 1000 is in an operation mode, such as a call mode, recording mode, and a voice recognition mode. The received audio signal may be further stored in the memory 1004 or transmitted via the communication component 1016. In some embodiments, the audio component 1010 further includes a speaker to output audio signals.

The I/O interface 1012 provides an interface between the processing component 1002 and peripheral interface modules, such as a keyboard, a click wheel, buttons, and the like. The buttons may include, but are not limited to, a home button, a volume button, a starting button, and a locking button.

The sensor component 1014 includes one or more sensors to provide status assessments of various aspects of the device 1000. For instance, the sensor component 1014 may detect an open/closed status of the device 1000, relative positioning of components, e.g., the display and the keypad, of the device 1000, a change in position of the device 1000 or a component of the device 1000, a presence or absence of user contact with the device 1000, an orientation or an acceleration/deceleration of the device 1000, and a change in temperature of the device 1000. The sensor component 1014 may include a proximity sensor configured to detect the presence of nearby objects without any physical contact. The sensor component 1014 may also include a light sensor, such as a CMOS or CCD image sensor, for use in imaging applications. In some embodiments, the sensor component 1014 may also include an accelerometer sensor, a gyroscope sensor, a magnetic sensor, a pressure sensor, or a temperature sensor.

The communication component 1016 is configured to facilitate communication, wired or wirelessly, between the device 1000 and other devices. The device 1000 may access a wireless network based on a communication standard, such as WiFi, 2G, or 3G, or a combination thereof. In one exemplary embodiment, the communication component 1016 receives a broadcast signal or broadcast associated information from an external broadcast management system via a broadcast channel. In one exemplary embodiment, the communication component 1016 further includes a near field communication (NFC) module to facilitate short-range communications. For example, the NFC module may be implemented based on a radio frequency identification (RFID) technology, an infrared data association (IrDA) technology, an ultra-wideband (UWB) technology, a Bluetooth (BT) technology, and other technologies.

In exemplary embodiments, the device 1000 may be implemented with one or more application specific integrated circuits (ASICs), digital signal processors (DSPs), digital signal processing devices (DSPDs), programmable logic devices (PLDs), field programmable gate arrays (FPGAs), controllers, micro-controllers, microprocessors, or other electronic components, for performing the above described methods. Each module, unit, or sub-module, such as discussed with respect to FIGS. 5-8, may take the form of a packaged functional hardware unit designed for use with other components, a portion of a program code (e.g., software or firmware) executable by the processor 1018, the processing component 922, or the processing circuitry that usually performs a particular function of related functions, or a self-contained hardware or software component that interfaces with a larger system, for example.

In exemplary embodiments, there is also provided a non-transitory computer-readable storage medium including instructions, such as included in the memory 1004, executable by the processor 1018 in the device 1000, for performing the above-described methods. For example, the non-transitory computer-readable storage medium may be a ROM, a RAM, a CD-ROM, a magnetic tape, a floppy disc, an optical data storage device, and the like.

In exemplary embodiments, there is also provided a non-transitory computer-readable storage medium storing instructions, such as stored in the memory, executable by the processor 1018 in the device 1000, for performing the above-described methods. For example, the non-transitory computer-readable storage medium may be a ROM, RAM, a CD-ROM, a magnetic tape, a floppy disc, an optical data storage device, and the like.

Other embodiments of the invention will be apparent to those skilled in the art from consideration of the specification and practice of the invention disclosed here. This application is intended to cover any variations, uses, or adaptations of the invention following the general principles thereof and including such departures from the present disclosure as come within known or customary practice in the art. It is intended that the specification and examples be considered as exemplary only, with a true scope and spirit of the invention being indicated by the following claims.

It will be appreciated that the present invention is not limited to the exact construction that has been described above and illustrated in the accompanying drawings, and that various modifications and changes may be made without departing from the scope thereof. It is intended that the scope of the invention only be limited by the appended claims.

What is claimed is:

1. A method, comprising:
acquiring a code portion and a data portion of a firmware program;
compressing the code portion and the data portion separately; and
configuring first description data corresponding to the firmware program, the first description data comprising first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

2. The method of claim 1, wherein acquiring a code portion and a data portion of the firmware program comprises:
determining a third storage address of the code portion and a fourth storage address of the data portion; and
retrieving the code portion based on the third storage address and retrieving the data portion based on the fourth storage address.

3. The method of claim 2, wherein determining a third storage address of the code portion and a fourth storage address of the data portion comprises:
retrieving second description data corresponding to the firmware program;
when the second description data contains the third storage address and the fourth storage address, determining the third storage address and the fourth storage address from the retrieved second description data; and
when the second description data contains an original storage address of the code portion, a size of the code portion, an original storage address of the data portion, and a size of the data portion, determining the third storage address based on the retrieved original storage address of the code portion and the retrieved size of the code portion and determining the fourth storage address based on the retrieved original storage address of the data portion and the retrieved size of the data portion.

4. The method of claim 1, wherein configuring first description data corresponding to the firmware program comprises:
configuring a first storage address where the compressed code portion is stored in the electronic device and a second storage address where the compressed data portion is stored in the electronic device, taking the first storage address as the first address data, and taking the second storage address as the second address data; or
configuring an original storage address of the compressed code portion in the electronic device and an original storage address of the compressed data portion in the electronic device, acquiring a size of the compressed code portion and a size of the compressed data portion; taking the original storage address of the compressed code portion and the size of the compressed code portion as the first address data;
and taking the original storage address of the compressed data portion and the size of the compressed data portion as the second address data; and
configuring the first decompression address and the second decompression address.

5. The method of claim 1, wherein configuring first description data corresponding to the firmware program further comprises:
acquiring a size of the code portion and a size of the data portion; and
storing the size of the code portion and the size of the data portion into the first description data.

6. The method of claim 1, wherein compressing the code portion and the data portion separately, comprises:
dividing at least one of the code portion and the data portion;
when the code portion is divided into a number m of segments, compressing the m segments of the code portion separately, and compressing the data portion;
when the data portion is divided into a number n of segments, compressing the n segments of the data portion separately, and compressing the code portion; and
when the code portion is divided into a number m of segments and the data portion is divided into a number n of segments, compressing the m segments of the code portion separately, and compressing the n segments of the data portion separately, wherein m and n are positive integers.

7. A method, comprising:
retrieving first description data corresponding to a firmware program, the first description data containing first address data regarding where a compressed code portion of the firmware program is stored in an electronic device, second address data regarding where a compressed data portion of the firmware program is stored in the electronic device, a first decompression address where the compressed code portion is to be decompressed in the electronic device, and a second decompression address where the compressed data portion is to be decompressed in the electronic device;
acquiring the compressed code portion based on the first address data, and acquiring the compressed data portion based on the second address data; and
decompressing the compressed code portion to the first decompression address, and decompressing the compressed data portion to the second decompression address.

8. The method of claim 7, wherein acquiring the compressed code portion based on the first address data, and acquiring the compressed data portion based on the second address data comprises:
determining a first storage address based on the first address data and determining a second storage address based on the second address data; and
retrieving the compressed code portion from the first storage address and retrieving the compressed data portion from the second storage address.

9. The method of claim 8, wherein determining a first storage address based on the first address data and determining a second storage address based on the second address data comprises:
if the first address data is the first storage address and the second address data is the second storage address, determining the first storage address and the second storage address based on the retrieved first description data; and
if the first address data is an original storage address of the compressed code portion and a size of the compressed code portion, and the second address data is an original storage address of the compressed data portion and a size of the compressed data portion, determining the first storage address based on the original storage address and the size of the compressed code portion, and determining the second storage address based on the original storage address and the size of the compressed data portion.

10. The method of claim 7, wherein the first description data further contains a size of an uncompressed code portion of the firmware program and a size of an uncompressed data portion of the firmware program, and the method further comprises:
calculating a total size of the uncompressed code portion and the uncompressed data portion;
examining whether the total size exceeds a space for running the firmware program in the electronic device; and
if the total size exceeds a space for running the firmware program, prompting an error of the firmware program.

11. A device, comprising:
a processor; and
a non-transitory storage memory for storing instructions executable by the processor;
wherein the processor is configured to perform:
acquiring a code portion and a data portion of a firmware program;
compressing the code portion and the data portion separately; and
configuring first description data corresponding to the firmware program, the first description data containing first address data regarding where the compressed code portion is stored in an electronic device, second address data regarding where the compressed data portion is stored in the electronic device, a first decompression address where the compressed code portion is to be decompressed in the electronic device, and a second decompression address where the compressed data portion is to be decompressed in the electronic device.

12. The device of claim 11, wherein acquiring a code portion and a data portion of the firmware program comprises:
determining a third storage 1 address of the code portion and a fourth storage address of the data portion; and
retrieving the code portion based on the third storage address and retrieving the data portion based on the fourth storage address.

13. The device of claim 12, wherein determining a third storage address of the code portion and a fourth storage address of the data portion comprises:
retrieving second description data corresponding to the firmware program;
when the second description data contains the third storage address and the fourth storage address, determining the third storage address and the fourth storage address from the retrieved second description data; and
when the second description data contains an original storage address of the code portion, a size of the code portion, an original storage address of the data portion, and a size of the data portion, determining the third storage address based on the retrieved original storage address of the code portion and the retrieved size of the code portion and determining the fourth storage address based on the retrieved original storage address of the data portion and the retrieved size of the data portion.

14. The device of claim 11, wherein configuring first description data corresponding to the firmware program comprises:
configuring a first storage address where the compressed code portion is stored in the electronic device and a second storage address where the compressed data portion is stored in the electronic device, taking the first storage address as the first address data, and taking the second storage address as the second address data; or
configuring an original storage address of the compressed code portion in the electronic device and an original storage address of the compressed data portion in the electronic device, acquiring a size of the compressed code portion and a size of the compressed data portion; taking the original storage address of the compressed code portion and the size of the compressed code portion as the first address data;
and taking the original storage address of the compressed data portion and the size of the compressed data portion as the second address data; and
configuring the first decompression address and the second decompression address.

15. The device of claim 11, wherein configuring first description data corresponding to the firmware program further comprises:
acquiring a size of the code portion and a size of the data portion; and
storing the size of the code portion and the size of the data portion into the first description data.

16. The device of claim 11, wherein compressing the code portion and the data portion separately, comprises:
dividing at least one of the code portion and the data portion;
when the code portion is divided into a number m of segments, compressing the m segments of the code portion separately, and compressing the data portion;
when the data portion is divided into a number n of segments, compressing the n segments of the data portion separately, and compressing the code portion; and
when the code portion is divided into a number m of segments and the data portion is divided into a number n of segments, compressing the m segments of the code portion separately, and compressing the n segments of the data portion separately, wherein m and n are positive integers.

17. A device, comprising:
a processor; and
a memory for storing instructions executable by the processor;
wherein the processor is configured to perform:
retrieving first description data corresponding to a firmware program, the first description data containing first address data regarding where a compressed code portion of the firmware program is stored in an electronic device, second address data regarding where a compressed data portion of the firmware program is stored in the electronic device, a first decompression address where the compressed code portion is to be decompressed in the electronic device, and a second decompression address where the compressed data portion is to be decompressed in the electronic device;
acquiring the compressed code portion based on the first address data, and acquiring the compressed data portion based on the second address data; and
decompressing the compressed code portion to the first decompression address, and decompressing the compressed data portion to the second decompression address.

18. The device of claim 17, wherein acquiring the compressed code portion based on the first address data, and acquiring the compressed data portion based on the second address data comprises:
determining a first storage address based on the first address data and determining a second storage address based on the second address data; and
retrieving the compressed code portion from the first storage address and retrieving the compressed data portion from the second storage address.

19. The device of claim 18, wherein determining a first storage address based on the first address data and determining a second storage address based on the second address data comprises:
if the first address data is the first storage address and the second address data is the second storage address, determining the first storage address and the second storage address based on the retrieved first description data; and
if the first address data is an original storage address of the compressed code portion and a size of the compressed code portion, and the second address data is an original storage address of the compressed data portion and a size of the compressed data portion, determining the first storage address based on the original storage address and the size of the compressed code portion, and determining the second storage address based on the original storage address and the size of the compressed data portion.

20. The device of claim 17, wherein the first description data further contains a size of an uncompressed code portion of the firmware program and a size of an uncompressed data portion of the firmware program, and the processor is further configured to perform:
calculating a total size of the uncompressed code portion and the uncompressed data portion;
examining whether the total size exceeds a space for running the firmware program in the electronic device; and
if the total size exceeds a space for running the firmware program, prompting an error of the firmware program.
